(19) United States
(12) Patent Application Publication
(10) Pub. No.: US 2026/0242930 A1
(43) Pub. Date: Aug. 20, 2026

(54) METHOD FOR CREATING THERMALLY CONDUCTIVE, ELECTRICALLY INSULATING MATERIALS

(71) Applicant: United Protective Technologies, LLC, Locust, NC (US)

(72) Inventors: Scott Robert Haynes, Monroe, NC (US); Cantwell George Carson, Pittsburgh, PA (US); Timothy Curtis Simmons, Jr., Charlotte, NC (US); Joseph James Rogers, III, Trinity, NC (US)

(73) Assignee: United Protective Technologies, LLC, Locust, NC (US)

(21) Appl. No.: 19/000,317

(22) Filed: Dec. 23, 2024

Related U.S. Application Data
(60) Provisional application No. 63/614,163, filed on Dec. 22, 2023.

(51) Int. Cl. C23C 14/32; C23C 14/06; C23C 14/08; C23C 14/50; C23C 16/34; C23C 16/36; C23C 16/40; C23C 16/46; C23C 16/505

(52) U.S. Cl. CPC C23C 14/325; C23C 14/0647; C23C 14/0664; C23C 14/082; C23C 14/50; C23C 16/342; C23C 16/36; C23C 16/403; C23C 16/46; C23C 16/505

(57) ABSTRACT

A system and method for creating thermally conductive, electrically insulating materials and a product of such method are provided. A thin film may be deposited onto a substrate such as a metallic heat spreader to provide electrically insulating properties while maintaining the thermal conductivity of the substrate. The film, which may be a carbon-based film or boron nitride-based film, may be deposited onto the substrate using chemical and/or physical vapor deposition processes. By adjusting various parameters of the processes, such as the thickness of the film, deposition temperature, interior pressures, precursor concentrations, and/or the like, a durable, thermally conductive yet electrically insulating film may be formed on the substrate.

### CROSS-REFERENCES AND RELATED APPLICATIONS

This application claims the benefit of priority under U.S.C. § 119 to U.S. Provisional Application No. 63/614,163, as filed on Dec. 22, 2023, which is hereby incorporated by reference in its entirety.

### STATEMENT OF FEDERALLY SPONSORED RESEARCH AND DEVELOPMENT

This invention was made with government support under Contract Number N68335-21-C-0332 awarded by the Department of the Navy. The government has certain rights in the invention.

### TECHNOLOGICAL FIELD

Example embodiments of the present disclosure relate to a system and method for creating thermally conductive, electrically insulating materials and a product of such method.

### BACKGROUND

Near Moore's Law increases in computing power density have provided for a variety of novel innovations in applications such as self-driving cars, robotics, avionics, portable electronics, power electronics, lithium-ion batteries and data storage. With this increasing demand for electronics miniaturization as well as the protection key components from shock, vibrations and environmental impacts in these applications, designers have foregone the use of traditional heat sinks in lieu of conducting heat to the chassis of the product. While spatially efficient, thermal dissipation has become a critical limiting factor for the performance, reliability, longevity, and safety of these systems. To manage these thermal loads, designers employ dynamic thermal throttling of performance which significantly reduces the computational capacity of the product limiting overall usability.

One of the greatest limitations in the heat rejection in these high-performance systems is the effective spread from small areas of high heat generation to the chassis. Although there are conventional methods to improve heat rejection through thermal interface materials (“TIM”), such as thermal pastes or greases, their effectiveness is limited due to their low thermal conductivity, high compression set, and their propensity for migration and cracking, which leads to decreased performance over time. Higher thermal conductivity materials such as copper may be employed as heat spreaders, but they are also electrically conductive and thus prevents them from being used in many applications, and often require TIMs to decrease thermal resistance.

While the application of pure diamond heat spreaders can achieve the desired performance, their manufacture is costly, time consuming, and is not conducive to many high conductivity substrates due to high temperatures required for fabrication. Accordingly, there is a need for a more cost effective and novel method of producing suitable coatings for heat spreader applications.

### BRIEF SUMMARY

The following presents a simplified summary of one or more embodiments of the present disclosure, in order to provide a basic understanding of such embodiments. This summary is not an extensive overview of all contemplated embodiments and is intended to neither identify key or critical elements of all embodiments nor delineate the scope of any or all embodiments. Its sole purpose is to present some concepts of one or more embodiments of the present invention in a simplified form as a prelude to the more detailed description that is presented later.

A system and method are provided for creating thermally conductive, electrically insulating materials. A thin film may be deposited onto a substrate such as a metallic heat spreader to provide electrically insulating properties while maintaining the thermal conductivity of the substrate. The film, which may be a carbon-based film or boron nitride-based film, may be deposited onto the substrate using chemical and/or physical vapor deposition processes. By adjusting various parameters of the processes, such as the thickness of the film, deposition temperature, interior pressures, precursor concentrations, and/or the like, a durable, thermally conductive yet electrically insulating film may be formed on the substrate with dramatically lower production times and cost when compared to conventional methods.

Accordingly, a first embodiment provides a method for creating thermally conductive, electrically insulating materials, the method comprising providing a substrate within a reaction chamber; includes heating the substrate to a target temperature; providing a target material within the reaction chamber; generating target particles by applying a current to the target material; and depositing a film on a surface of the substrate, the film comprising the target particles.

In a first aspect of the first embodiment, the target material is a gaseous precursor of the film, wherein the target particles comprise charged ions of the gaseous precursor, wherein generating the target particles further comprises introducing the gaseous precursor into the reaction chamber such that at least a portion of the gaseous precursor is positioned between a first electrode and a second electrode within the reaction chamber; generating an electrical field within the reaction chamber to generate a plasma of the gaseous precursor; and igniting the plasma to generate the charged ions.

In a second aspect, alone or in combination with the first aspect of the first embodiment, the target material is a cathode target, wherein the target particles comprise a vapor of the target material, wherein generating the target particles further comprises activating an arc source located proximate to the cathode target within the reaction chamber; and generating an electrical arc that impacts a surface of the cathode target, wherein the electrical arc causes at least a portion of the cathode target to vaporize.

In a third aspect, alone or in combination with any of the previous aspects of the first embodiment, the method further comprises evacuating an interior of the reaction chamber to a target interior pressure.

In a fourth aspect, alone or in combination with any of the previous aspects of the first embodiment, the target interior pressure ranges from about 1 torr to 2 torr.

In a fifth aspect, alone or in combination with any of the previous aspects of the first embodiment, the target temperature ranges from about 200 degrees Celsius to 400 degrees Celsius.

In a sixth aspect, alone or in combination with any of the previous aspects of the first embodiment, a thickness of the film ranges from about 5 microns to 20 microns.

In a seventh aspect, alone or in combination with any of the previous aspects of the first embodiment, the film is a carbon-based film comprising at least one of amorphous carbon, graphitic carbon, or diamond carbon.

In an eighth aspect, alone or in combination with any of the previous aspects of the first embodiment, the film is a boron nitride-based film comprising at least one of amorphous boron nitride, hexagonal boron nitride, or cubic boron nitride.

In a ninth aspect, alone or in combination with any of the previous aspects of the first embodiment, the film is a beryllium oxide-based film.

In a tenth aspect, alone or in combination with any of the previous aspects of the first embodiment, the film is a silicon carbonitride-based film.

In an eleventh aspect, alone or in combination with any of the previous aspects of the first embodiment, the substrate is at least one of a heat spreader, heat sink, or heat exchanger.

In a twelfth aspect, alone or in combination with any of the previous aspects of the first embodiment, the substrate is constructed from copper or aluminum.

A second embodiment provides a system for creating thermally conductive, electrically insulating materials, the system comprising a reaction chamber comprising an interior; an output port operatively coupled to the interior of the reaction chamber, the output port comprising a vacuum pump; and an input port operatively coupled to the interior of the reaction chamber, wherein the interior of the reaction chamber comprises one or more electrodes operatively coupled to a power source; a substrate positioned adjacent to or reversibly attached to a substrate holder, wherein the substrate holder comprises a heating element; and a mass of target particles, wherein the target particles form a film on a surface of the substrate.

In a first aspect of the second embodiment, target particles comprise charged ions formed from a plasma formed from a gaseous precursor of the film, wherein the power source is a radio-frequency (“RF”) power source that generates an electrical field within the reaction chamber that creates the plasma from the gaseous precursor.

In a second aspect, alone or in combination with the first aspect of the second embodiment, the one or more electrodes comprises a cathode target, wherein the target particles comprise a vapor formed from the cathode target, wherein the reaction chamber further comprises an arc source positioned proximate to the cathode target, wherein the arc source, when activated, causes at least a portion of the cathode target to vaporize.

In a third aspect, alone or in combination with any of the previous aspects of the second embodiment, a thickness of the film ranges from about 5 microns to 20 microns.

In a fourth aspect, alone or in combination with any of the previous aspects of the second embodiment the film is a carbon-based film comprising at least one of amorphous carbon, graphitic carbon, or diamond carbon.

In a fifth aspect, alone or in combination with any of the previous aspects of the second embodiment the film is a boron nitride-based film comprising at least one of amorphous boron nitride, hexagonal boron nitride, or cubic boron nitride.

In a sixth aspect, alone or in combination with any of the previous aspects of the second embodiment the substrate is at least one of a heat spreader, heat sink, or heat exchanger.

A third embodiment provides a product, comprising a substrate having a surface, wherein the substrate has a high thermal conductivity; and a film applied to the surface of the substrate, wherein the film is a vapor deposited film having a high thermal conductivity and a high electrical resistivity.

In a first aspect of the third embodiment, the thermal conductivity of the substrate is at least 100 W/m·k.

In a second aspect, alone or in combination with any of the previous aspects of the third embodiment, the thermal conductivity of the substrate ranges from about 150 W/m·k to about 400 W/m·k.

In a third aspect, alone or in combination with any of the previous aspects of the third embodiment, the thermal conductivity of the substrate is greater than 400 W/m·k.

In a fourth aspect, alone or in combination with any of the previous aspects of the third embodiment, the thermal conductivity of the film is at least 1 W/m·k.

In a fifth aspect, alone or in combination with any of the previous aspects of the third embodiment, the thermal conductivity of the film ranges from about 2 W/m·k to about 5 W/m·k.

In a sixth aspect, alone or in combination with any of the previous aspects of the third embodiment, the thermal conductivity of the film is greater than 100 W/m·k.

In a seventh aspect, alone or in combination with any of the previous aspects of the third embodiment, the electrical resistivity of the film is at least 1 MΩ/m.

In an eighth aspect, alone or in combination with any of the previous aspects of the third embodiment, a thermal resistivity of the film is less than 1 m·K/W.

In a ninth aspect, alone or in combination with any of the previous aspects of the third embodiment, a dielectric strength of the film is at least 500 V/μm.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Having thus described embodiments of the disclosure in general terms, reference will now be made the accompanying drawings. The components illustrated in the figures may or may not be present in certain embodiments described herein. Some embodiments may include fewer (or more) components than those shown in the figures.

FIG. 1 illustrates a system for creating thermally conductive, electrically insulating materials, in accordance with an embodiment of the disclosure;

FIG. 2 illustrates an alternative system for creating thermally conductive, electrically insulating materials, in accordance with an embodiment of the disclosure; and

FIG. 3 illustrates a process flow for creating thermally conductive, electrically insulating materials, in accordance with an embodiment of the disclosure.

### DETAILED DESCRIPTION

Embodiments of the present disclosure will now be described more fully hereinafter with reference to the accompanying drawings, in which some, but not all, embodiments of the disclosure are shown. Indeed, the disclosure may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Furthermore, when it is said herein that something is “based on” something else, it may be based on one or more other things as well. In other words, unless expressly indicated otherwise, as used herein “based on” means “based at least in part on” or “based at least partially on.” Like numbers refer to like elements throughout.

As used herein, “film” or “coating” may refer to any continuous or non-continuous material that may be formed, deposited, layered, or placed on or adjacent to a surface of a structure. In some embodiments, a film may comprise nanomaterials such as nanoparticles, nanosheets, nanolayers, or other such nanostructures.

Embodiments of the present disclosure provide a method for creating thermally conductive, electrically insulating materials. In this regard, a substrate such as a heat spreader (e.g., a metallic heat spreader for a processor, integrated circuit, voltage regulator module or “VRM,” and/or the like) may be coated with a thermally conductive, electrically insulating (“TCEI”) film. The TCEI film may be a nanocomposite coating being comprised of one or more materials. In one embodiment, the TCEI film may be a carbon based film comprising amorphous carbon (e.g., a mixture of crystalline forms of carbon, which may include cubic carbon and graphitic carbon structures, within an amorphous carbon matrix) or other carbon-based structures (e.g., graphenes, graphitic carbons, diamond-like carbons or “DLC”). In another embodiment, the TCEI film may be a boron based film (e.g., boron nitride, or “BN”) comprising amorphous boron nitride (e.g., a mixture of crystalline forms of BN, which may include cubic BN and hexagonal BN in an amorphous BN matrix). In yet another embodiment, the TCEI film may be a beryllium-based film comprising beryllium oxide. In yet another embodiment, the TCEI film may be a silicon-based film comprising amorphous silicon carbonitride (“SiCN”) or silicon carbide (“SiC”). In one embodiment, the TCEI film may comprise a plurality of discrete layers, where each layer comprises at least one of the materials described above (e.g., carbon-based structures, boron-based structures, beryllium-based structures, and/or silicon-based structures).

The film may be applied or deposited onto the surface of the substrate (e.g., a heat spreader, heat sink, heat exchanger, heat pipe, and/or the like). In this regard, “applied” or “deposited” as used herein may include various techniques for layering or coating a surface of the substrate with the film by physical methods (e.g., the film is condensed onto the substrate) and/or chemical methods (e.g., the film is chemically bonded to the substrate). For instance, such techniques may include physical vapor deposition (“PVD”), cathodic arc deposition (“Arc-PVD”), evaporative deposition, sputtering and/or magnetron sputtering, chemical vapor deposition (“CVD”), hybrid plasma enhanced CVD (“PECVD”), low pressure or ultrahigh vacuum CVD (“LPCVD” or “UHVCVD”), and//or the like. In an exemplary embodiment, a film may be deposited onto a substrate (e.g., a heat spreader or heat sink) using PECVD. In such an embodiment, the substrate may be placed in a low pressure reaction chamber between a cathode and anode. For instance, the reaction chamber may have an internal pressure ranging from about 0.005 Torr to 10 Torr. In other embodiments, the pressure of the reaction chamber may range from about 0.05 Torr to 5 Torr. In yet other embodiments, the pressure of the reaction chamber may range from about 1 Torr to 5 Torr. In some embodiments, the substrate may be heated to a temperature of between about 200 degrees Fahrenheit and 1000 degrees Fahrenheit. In other embodiments, the substrate may be heated to a temperature of between about 300 degrees Fahrenheit and 800 degrees Fahrenheit. In yet other embodiments, the substrate may be heated to a temperature of between about 400 degrees Fahrenheit and 600 degrees Fahrenheit.

Gaseous precursors and/or reactants (e.g., precursors or reactants containing the materials to be deposited onto the substrate) may be introduced into the reaction chamber. For instance, the precursors may contain carbon, boron, beryllium, silicon, nitrogen, background/carrier gases (e.g., argon), and/or other materials needed to generate the films described herein. Subsequently, a radio frequency (“RF”) potential may be used to generate a plasma within the reaction chamber (e.g., in between the cathode and anode) from the gaseous precursors and/or reactants, thereby inducing a chemical reaction (e.g., ignition of the plasma) by which such precursors and/or reactants are transformed and deposited onto the substrate as a film in solid form. Whereas conventional methods may prevent the deposition of high thermal conductivity materials due to high deposition temperatures that may subject the materials to thermal decomposition and/or damage, the relatively lower deposition temperatures of PECVD may allow such materials to be deposited without the issues associated with said conventional methods.

In another embodiment, the film may be deposited onto the substrate using Arc-PVD. In such an embodiment, an electric arc may be used to vaporize at least a portion of a cathode target (e.g., where the target material may comprise carbon, boron, beryllium, silicon, and/or the like). In this regard, the arc may comprise a series of high current electrical strikes, where each strike impacts a localized area on the surface of the cathode target. The vaporized portions of the cathode target may condense on a substrate within a low-pressure chamber. By using PECVD and/or Arc-PVD techniques as described herein, a film may be deposited onto a substrate that may otherwise be electrically conductive (e.g., a metal substrate such as a copper heat spreader) such that the coated substrate may as a whole be thermally conductive and electrically insulating.

It should be understood that unless otherwise indicated, values regarding thermal conductivity, thermal resistivity, electrical conductivity, and electrical resistance may be dependent on an operating temperature of the device to which the substrate and/or film is connected. In this regard, the operating temperature of the device may range from about 20 degrees Celsius to about 120 degrees Celsius. In other embodiments, the operating temperature may range from about 30 degrees Celsius to about 100 degrees Celsius. In yet other embodiments, the operating temperature may range from about 35 degrees Celsius to about 95 degrees Celsius. In yet other embodiments, the operating temperature may range from 120 degrees Celsius to 650 degrees Celsius.

In certain embodiments, the substrate may be a component such as a heat spreader, heat sink, heat pipe, and/or the like, where the substrate may be constructed from and/or comprise one or more materials including copper, aluminum, various forms of carbon (e.g., diamond, graphite, graphene, and/or the like), alloys thereof, and/or the like. In such embodiments, the substrate may have a high thermal conductivity value. Accordingly, in some embodiments, the substrate may have a thermal conductivity value of at least 100 W/m·K. In another embodiment, the substrate may have a thermal conductivity value of at least 125 W/m·K. In another embodiment, the substrate may have a thermal conductivity value of at least 150 W/m·K. In another embodiment, the substrate may have a thermal conductivity value of at least 175 W/m·K. another embodiment, the substrate may have a thermal conductivity value of at least 200 W/m·K. In another embodiment, the substrate may have a thermal conductivity value of at least 225 W/m·K. In another embodiment, the substrate may have a thermal conductivity value of at least 250 W/m·K. In another embodiment, the substrate may have a thermal conductivity value of at least 275 W/m·K. In another embodiment, the substrate may have a thermal conductivity value of at least 300 W/m·K. In another embodiment, the substrate may have a thermal conductivity value of at least 325 W/m·K. In another embodiment, the substrate may have a thermal conductivity value of at least 350 W/m·K. In another embodiment, the substrate may have a thermal conductivity value of at least 375 W/m·K. In another embodiment, the substrate may have a thermal conductivity value of at least 400 W/m·K. In another embodiment, the substrate may have a thermal conductivity value of greater than 400 W/m·K. In other embodiments, the substrate may have a thermal conductivity that ranges from at least 150 W/m·K and up to 400 W/m·K. In other embodiments, the substrate may have a thermal conductivity that ranges from at least 200 W/m·K and up to 300 W/m·K.

In an exemplary embodiment, the substrate may have a thermal resistivity value of less than or equal to 10⁻⁴ m·K/W. In another embodiment, the substrate may have a thermal resistivity value of less than or equal to 5×10⁻³ m·K/W. In another embodiment, the substrate may have a thermal resistivity value of less than or equal to 10⁻³ m·K/W. In another embodiment, the substrate may have a thermal resistivity value of less than or equal to 5×10⁻²m·K/W. In another embodiment, the substrate may have a thermal resistivity value of less than or equal to 10⁻² m·K/W. In another embodiment, the substrate may have a thermal resistivity value of greater than 10⁻² m·K/W. In another embodiment, the substrate may have a thermal resistivity value that ranges from about 10⁻⁴ m·K/W to about 10⁻² m·K/W. In another embodiment, the substrate may have a thermal resistivity value that ranges from about 1×10⁻⁴ m·K/W to about 5×10⁻⁴ m·K/W. In another embodiment, the substrate may have a thermal resistivity value that ranges from about 1×10⁻⁴ m·K/W to about 5×10⁻⁴ m·K/W. In another embodiment, the substrate may have a thermal resistivity value that ranges from about 1×10⁻³ m·K/W to about 4×10⁻³ m·K/W. In another embodiment, the substrate may have a thermal resistivity value that ranges from about 5×10⁻³ m·K/W to about 8×10⁻³ m·K/W.

In an exemplary embodiment, the substrate may have an electrical conductivity of at least 10⁴ S/m. In another embodiment, the substrate may have an electrical conductivity of at least 10⁵ S/m. In another embodiment, the substrate may have an electrical conductivity of at least 10⁶ S/m. In another embodiment, the substrate may have an electrical conductivity of at least 10⁷ S/m. In another embodiment, the substrate may have an electrical conductivity of at least 10⁸ S/m. In another embodiment, the substrate may have an electrical conductivity of greater than 10⁸ S/m. In another embodiment, the substrate may have an electrical conductivity that ranges from at least 10⁵ S/m and up to 10⁹ S/m. In another embodiment, the substrate may have an electrical conductivity that ranges from at least 10⁶ S/m and up to 10⁸ S/m.

In an exemplary embodiment, the substrate may have an electrical resistivity value of less than or equal to 10⁻¹⁰ Ω/m. In another embodiment, the substrate may have an electrical resistivity value of less than or equal to 10⁻⁹ Ω/m. In another embodiment, the substrate may have an electrical resistivity value of less than or equal to 10⁻⁸ Ω/m. In another embodiment, the substrate may have an electrical resistivity value of less than or equal to 10⁻⁷ Ω/m. In another embodiment, the substrate may have an electrical resistivity value of less than or equal to 10⁻⁶ Ω/m. In another embodiment, the substrate may have an electrical resistivity value of less than or equal to 10⁻⁵ Ω/m. In another embodiment, the substrate may have an electrical resistivity value of less than or equal to 10⁻⁴ Ω/m. In another embodiment, the substrate may have an electrical resistivity value of greater than 10⁻⁴ Ω/m. In another embodiment, the substrate may have an electrical resistivity that ranges from about 10⁻⁹ Ω/m to about 10⁻⁵ Ω/m. In another embodiment, the substrate may have an electrical resistivity that ranges from about 10⁻⁸ Ω/m to about 10⁻⁶ Ω/m.

The film that is applied to the surface of the substrate may have a high electrical resistivity (and low electrical conductivity) and a high thermal conductivity (and low thermal resistivity). In this regard, the film may be constructed such that the film has sufficient electrical resistivity and breakdown voltage values to provide electrical isolation to the substrate and other associated components while having sufficient thermal conductivity to avoid interfering with transfer of heat from electrical components (e.g., transistors) through the substrate (e.g., a heat spreader). Accordingly, in some embodiments, the film may have thermal conductivity value of at least 0.5 W/m·K. In another embodiment, the film may have thermal conductivity value of at least 1 W/m·K. In another embodiment, the film may have thermal conductivity value of at least 3 W/m·K. In another embodiment, the film may have thermal conductivity value of at least 10 W/m·K. In another embodiment, the film may have thermal conductivity value of at least 25 W/m·K. In another embodiment, the film may have thermal conductivity value of at least 50 W/m·K. In another embodiment, the film may have thermal conductivity value of at least 75 W/m·K. In another embodiment, the film may have thermal conductivity value of at least 100 W/m·K. In another embodiment, the film may have thermal conductivity value of at least 150 W/m·K. In another embodiment, the film may have thermal conductivity value of at least 200 W/m·K. In another embodiment, the film may have thermal conductivity value of at least 250 W/m·K. In another embodiment, the film may have thermal conductivity value of at least 300 W/m·K. In another embodiment, the film may have thermal conductivity value of at least 350 W/m·K. In another embodiment, the film may have thermal conductivity value of at least 400 W/m·K. In another embodiment, the film may have thermal conductivity value of at least 500 W/m·K. In another embodiment, the film may have thermal conductivity value of at least 600 W/m·K.

In another embodiment, the film may have thermal conductivity of greater than 600 W/m·K. For instance, in one embodiment, the film may have a thermal conductivity of at least 800 W/m·K. In another embodiment, the film may have a thermal conductivity of at least 1600 W/m·K. In another embodiment, the film may have a thermal conductivity of at least 2000 W/m·K. In another embodiment, the film may have a thermal conductivity that ranges from about 2 W/m·K to about 5 W/m·K. In another embodiment, the film may have a thermal conductivity of about 10 W/m·K to about 2000 W/m·K. In another embodiment, the film may have a thermal conductivity of about 30 W/m·K to about 1500 W/m·K. In another embodiment, the film may have a thermal conductivity of about 50 W/m·K to 1000 W/m·K. In another embodiment, the film may have a thermal conductivity of about 100 W/m·K to 500 W/m·K. In another embodiment, the film may have a thermal conductivity of about 1 W/m·K to 50 W/m·K. In another embodiment, the film may have a thermal conductivity of about 50 W/m·K to 100 W/m·K.

In an exemplary embodiment, the film may have a thermal resistivity value of less than or equal to 10⁴ m·K/W. In another embodiment, the film may have a thermal resistivity value of less than or equal to 5×10⁻³ m·K/W. In another embodiment, the film may have a thermal resistivity value of less than or equal to 10⁻³ m·K/W. In another embodiment, the film may have a thermal resistivity value of less than or equal to 5×10⁻² m·K/W. In another embodiment, the film may have a thermal resistivity value of less than or equal to 10⁻²m·K/W.

In another embodiment, the film may have a thermal resistivity value of greater than 10⁻² m·K/W. For instance, in one embodiment, the film may have a thermal resistivity value of about 10⁻¹ m·K/W. In another embodiment, the film may have a thermal resistivity value of about 1 m·K/W. In another embodiment, the film may have a thermal resistivity value that ranges from about 10⁻⁴ m·K/W to about 10⁻² m·K/W. In another embodiment, the film may have a thermal resistivity value that ranges from about 1×10⁻⁴ m·K/W to about 5×10⁻⁴ m·K/W. In another embodiment, the film may have a thermal resistivity value that ranges from about 1×10⁻⁴ m·K/W to about 5×10⁻⁴m·K/W. In another embodiment, the film may have a thermal resistivity value that ranges from about 1×10⁻³ m·K/W to about 4×10⁻³ m·K/W. In another embodiment, the film may have a thermal resistivity value that ranges from about 5×10⁻³ m·K/W to about 8×10⁻³ m·K/W.

In an exemplary embodiment, the film may have an electrical resistance (which may also be referred to herein as “electrical resistivity”) of at least 10⁻¹ MΩ·m. In another embodiment, the film may have an electrical resistance of at least 0.25 MΩ·m. In another embodiment, the film may have an electrical resistance of at least 0.5 MΩ·m. In another embodiment, the film may have an electrical resistance of at least 0.75 MΩ·m. In another embodiment, the film may have an electrical resistance of at least 1 MΩ·m. In another embodiment, the film may have an electrical resistance of at least 1.5 MΩ·m. In another embodiment, the film may have an electrical resistance of at least 2 MΩ·m. In another embodiment, the film may have an electrical resistance of at least 2.5 MΩ·m.

In another embodiment, the film may have an electrical resistance of greater than 2.5 MΩ·m. For instance, in one embodiment, the film may have an electrical resistance of at least 5 MΩ·m. In another embodiment, the film may have an electrical resistance of at least than 10 MΩ·m. the film may have an electrical resistance of at least 100 MΩ·m. In another embodiment, the film may have an electrical resistance of at least 1 GΩ·m. In another embodiment, the film may have an electrical resistance of at least 10 GΩ·m. In another embodiment, the film may have an electrical resistance of at least 100 GΩ·m. In another embodiment, the film may have an electrical resistance of at least 1 TΩ·m. In another embodiment, the film may have an electrical resistance of at least 1 EΩ·m.

In an exemplary embodiment, the film may have an electrical conductivity of less than or equal to 10⁻¹⁴ S/m. In another embodiment, the film may have an electrical conductivity of less than or equal to 10⁻¹³ S/m. In another embodiment, the film may have an electrical conductivity of less than or equal to 10⁻¹² S/m. In another embodiment, the film may have an electrical conductivity of less than or equal to 10⁻¹⁰ S/m. In another embodiment, the film may have an electrical conductivity of less than or equal to 10⁻⁸ S/m. In another embodiment, the film may have an electrical conductivity of less than or equal to 10⁻⁶ S/m. In another embodiment, the film may have an electrical conductivity of less than or equal to 10⁻⁴ S/m. In another embodiment, the film may have an electrical conductivity of less than or equal to 10⁻² S/m. In another embodiment, the film may have an electrical conductivity of less than or equal to 10⁻¹ S/m. In another embodiment, the film may have an electrical conductivity of less than or equal to 1 S/m. In another embodiment, the film may have an electrical conductivity of less than or equal to 2 S/m. In another embodiment, the film may have an electrical conductivity of less than or equal to 10 S/m. In another embodiment, the film may have an electrical conductivity of less than or equal to 50 S/m. In another embodiment, the film may have an electrical conductivity of less than or equal to 10² S/m. In another embodiment, the film may have an electrical conductivity of less than or equal to 5×10² S/m. In another embodiment, the film may have an electrical conductivity of less than or equal to 1×10³ S/m. In another embodiment, the film may have an electrical conductivity of less than or equal to 5×10³ S/m. In another embodiment, the film may have an electrical conductivity of less than or equal to 1×10⁻⁴ S/m. In one embodiment, the film may have an electrical conductivity that ranges from about 1×10⁻¹⁴ S/m to about 5×10⁻¹² S/m. In another embodiment, the film may have an electrical conductivity that ranges from about 1×10⁻¹³ S/m to about 5×10⁻¹² S/m. In another embodiment, the film may have an electrical conductivity that ranges from about 1×10⁻³ S/m to about 1×10⁻¹ S/m. In another embodiment, the film may have an electrical conductivity that ranges from about 1×10⁻¹ S/m to about 5×10⁻¹ S/m. In another embodiment, the film may have an electrical conductivity that ranges from about 1 S/m to about 10 S/m. In another embodiment, the film may have an electrical conductivity that ranges from about 50 S/m to about 5×10² S/m.

In an exemplary embodiment, the film may have a breakdown voltage (which may also be referred to herein as “dielectric strength”) of at least 10 V/μm. In another embodiment, the film may have a breakdown voltage of at least 50 V/μm. In another embodiment, the film may have a breakdown voltage of at least 100 V/μm. In another embodiment, the film may have a breakdown voltage of at least 200 V/μm. In another embodiment, the film may have a breakdown voltage of at least 300 V/μm. In another embodiment, the film may have a breakdown voltage of at least 400 V/μm. In another embodiment, the film may have a breakdown voltage of at least 500 V/μm. In another embodiment, the film may have a breakdown voltage of at least 600 V/μm. In another embodiment, the film may have a breakdown voltage of at least 700 V/μm. In another embodiment, the film may have a breakdown voltage of at least 800 V/μm. In another embodiment, the film may have a breakdown voltage of at least 900 V/μm. In another embodiment, the film may have a breakdown voltage of at least 1000 V/μm. In another embodiment, the film may have a breakdown voltage of at least 1100 V/μm. In another embodiment, the film may have a breakdown voltage of at least 1200 V/μm. In another embodiment, the film may have a breakdown voltage of at least 1300 V/μm. In another embodiment, the film may have a breakdown voltage of at least 1400 V/μm. In another embodiment, the film may have a breakdown voltage of at least 1500 V/μm. In another embodiment, the film may have a breakdown voltage of at least 1600 V/μm. In another embodiment, the film may have a breakdown voltage of at least 1700 V/μm. In another embodiment, the film may have a breakdown voltage of at least 1800 V/μm. In another embodiment, the film may have a breakdown voltage of at least 1900 V/μm. In another embodiment, the film may have a breakdown voltage of at least 2000 V/μm. In one embodiment, the film may have a breakdown voltage that ranges from about 100 V/μm to about 400 V/μm. In another embodiment, the film may have a breakdown voltage that ranges from about 400 V/μm to about 700 V/μm. In another embodiment, the film may have a breakdown voltage that ranges from about 700 V/μm to about 1000 V/μm. In another embodiment, the film may have a breakdown voltage that ranges from about 1000 V/μm to about 1500 V/μm. In another embodiment, the film may have a breakdown voltage that ranges from about 1500 V/μm to about 2000 V/μm.

Various parameters associated with the film may be modified such that the resulting product (e.g., the coated substrate) may have the necessary characteristics for the application. For instance, the parameters may further include deposition temperature, pre and post deposition annealing, coating chemistries or compositions, reaction chamber pressures, RF bias power, and/or the like. In an exemplary embodiment, if the desired product is a thermally conductive, electrically insulating heat spreader (e.g., for use with electronics in commercial or military applications), the parameters may be modified such that the coated heat spreader has a breakdown voltage of about 100 to 2000 V/μm and/or an electrical resistance of about 0.5 MΩ to 5 MΩ. In some embodiments, the coated heat spreader may have a breakdown voltage of about 200 to 1500 V/μm and/or an electrical resistance of about 0.8 MΩ to 2 MΩ. In spite of the electrical resistance, the heat spreader may maintain a high level of thermal conductivity. Accordingly, in some embodiments, the heat spreader may have a thermal conductivity value of about 100 to 5000 W/m·K. In other embodiments, the thermal conductivity value may range from about 300 to 2000 W/m·K. In yet other embodiments, the thermal conductivity value may range from about 500 to 1200 W/m·K.

The parameters to be modified may further include film thickness, which may be varied such that the film is thin enough to maintain sufficient thermal conductivity for the application (e.g., in some embodiments, a thermal resistance of less than 60 K·cm²/kW) while also being thick enough to prevent electrical shorts and/or arcing. To this end, in some embodiments, the thickness of the coating may range from about 0.1 μm to 50 μm. In other embodiments, the thickness may range from about 0.5 μm to 25 μm. In yet other embodiments, the thickness may range from about 1 μm to 10 μm.

The above parameters, among others, may be controlled to minimize coating stress values of the film. In this regard, in some embodiments, the coating stress levels of the film may range from about 50 MPa to 500 MPa. In yet other embodiments, the coating stress levels may range from about 100 MPa to 300 MPa. By minimizing coating stress, the system may allow for the creation of a more durable, defect-free coating with a higher coating thickness before the coating fails. Stress may be measured via a thin film stress measurement system that operates by measuring the change in the radius of curvature of a wafer of known thickness. Based on this change in radius of curvature, or deflection, the internal coating stress can be measured. Such a system utilizes a scanning laser and detector configuration to generate a three-dimensional mapping of a two-to-eight-inch wafer. This data can then be used to generate the curvature of the wafer which can then be used to calculate the internal stress of the coating.

In some embodiments, the concentration of nitrogen gas within the reaction chamber may be another parameter to be controlled during the film deposition process. In an exemplary embodiment, in generating an SiCN-based TCEI film, the flow of nitrogen gas (N₂) may be controlled relative to the background gas(es) (e.g., argon, or “Ar”) during CVD or PVD based processes. Accordingly, in some embodiments, the ratio of N₂ to Ar may range from about 0.05 and 5, which may lead an increased electrical resistivity (or lower electrical conductivity) of the deposited film. In other embodiments, the ratio of N₂ to Ar may range from about 0.6 to 1.

In some embodiments, a protective top layer or coating may be applied to the surface of the film to remedy the appearance of structural defects in the coating, such as the development of pinholes, cracks, incomplete or poor adhesion, adsorbed or imbedded contaminants, weaknesses in the finish or surface, and/or the like. Accordingly, in some embodiments, the top layer may be formed on the surface of the film through atomic layer deposition (“ALD”). In such an embodiment, the surface of the film may be exposed to a series of gas phases of precursors to form a thin coating on the surface of the film. In some embodiments, the precursors may include at least partially the same materials used to create the TCEI film. For instance, if the TCEI film is a film comprising amorphous carbon, the precursors may include carbon-based precursors. A first precursor or reactant may be introduced into the reaction chamber with the substrate (e.g., a heat spreader that has been coated with the TCEI film), thereby allowing the first precursor or substrate to react with the reactive sites on the surface of the film. The excess amounts of first precursor or substrate may be purged from the reaction chamber before introducing the second precursor or reactant. In this way, the number of gas phase cycles may be repeated, if necessary, until the structural defects of the TCEI film have been remedied.

The systems and methods described herein provide numerous advantages over existing heat rejection technologies. For instance, by selecting the appropriate processes (e.g., PECVD, Arc-PVD, or the like) to deposit thin TCEI film coatings on heat spreader substrates (e.g., substrates that may be manufactured from electrically conductive materials, such as copper), the method may produce a heat spreader with high thermal conductivity and protection against shorts at a significantly lower cost and faster manufacturing times compared to heat spreaders treated using conventional methods (e.g., using a pure diamond coating).

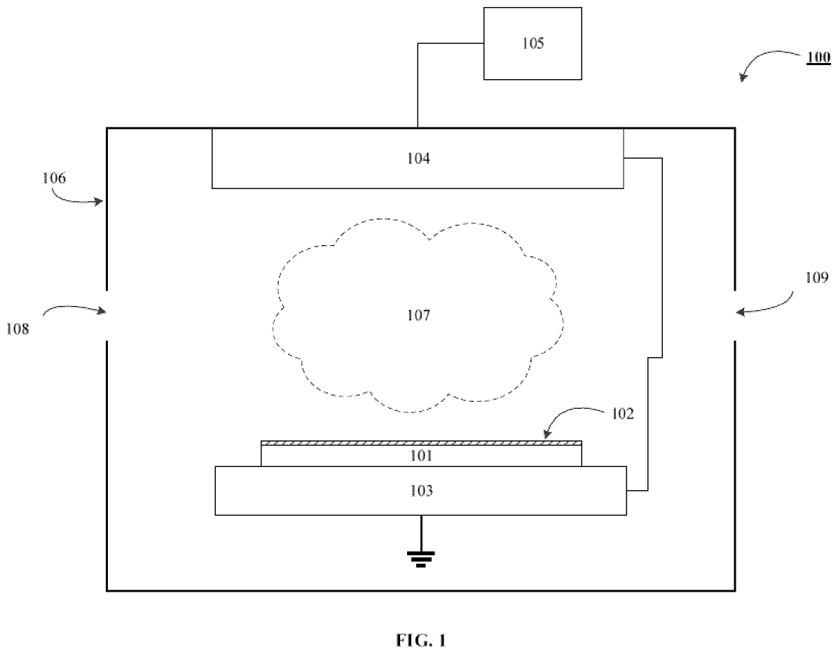

Turning now to the figures, FIG. 1 illustrates a system 100 for creating thermally conductive, electrically insulating materials, in accordance with an embodiment of the disclosure. In one embodiment, the system 100 may be a system for depositing a film 102 onto a substrate 101 through plasma-enhanced CVD. In such an embodiment, the system 100 may comprise a reaction chamber 106 structured to contain the substrate 101 therein. The substrate 101 may be supported by a first electrode 103 (e.g., an anode) that is located below a second electrode 104 (e.g., a cathode) that is operatively coupled to a power supply 105 (e.g., an RF power supply). In some embodiments, the first electrode 103 may comprise a heating element (e.g., a metallic heating coil, ceramic heater, thick film heater, and/or the like) that may be used to heat the substrate 101 to a specified temperature (e.g., from about 150 degrees Celsius to about 450 degrees Celsius). It should be appreciated while a single first electrode 103 and single second electrode 104 are depicted in FIG. 1, it is within the scope of the disclosure for the system to comprise multiple first electrodes (e.g., multiple anodes) and/or multiple second electrodes (e.g., multiple cathodes).

The interior of the reaction chamber 106 may be evacuated through an output port 109 (e.g., using a vacuum pump, exhaust system, or the like) such that a low interior pressure is achieved within the reaction chamber 106. It should be appreciated that the output port 109 as shown in FIG. 1 illustrates just one possible configuration. For instance, in other embodiments, the output port 109 may be located on a bottom floor of the interior of the reaction chamber 106. One or more precursors may be introduced into the reaction chamber 106 through input port 108 (e.g., reactants in gaseous form). In other embodiments, the one or more precursors may be introduced through one or more apertures within the second electrode 104 (e.g., a “showerhead” configuration). The one or more precursors may include, for instance, a gaseous carbon-containing gas (e.g., methane, or the like). Once the precursors are introduced into the reaction chamber 106, the activation of the power supply 105 may cause an electrical discharge (e.g., alternating current or “AC”, direct current or “DC”, or the like) between the first electrode 103 and the second electrode 104, thereby generating a chemically active plasma 107 from the precursors between the first electrode 103 and the second electrode 104. Subsequently, the creation of the plasma 107 may cause the deposition of a film 102 on a surface of the substrate 101. Various parameters of the deposition process, such as the composition of the precursors and/or film 102, the resulting thickness of the film 102, internal reaction chamber temperatures and/or pressures, substrate temperatures, coating stress, and/or the like may be modified to ensure that the film 102 provides sufficient electrical insulating properties (e.g., sufficient breakdown voltage, electrical resistance, and/or the like) without hindering the thermal conductivity of the substrate, while also being significantly more resource-efficient to produce.

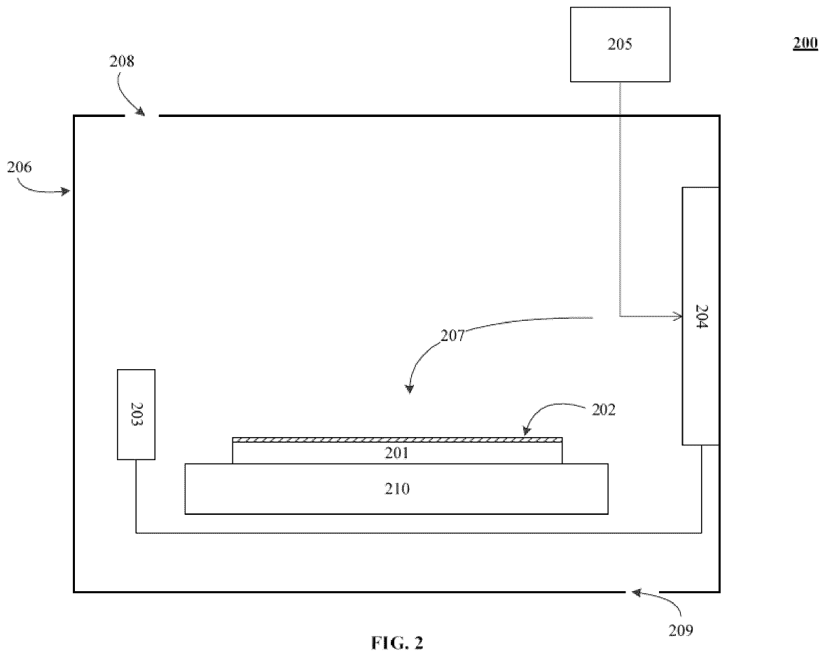

FIG. 2 illustrates an alternative system 200 for creating thermally conductive, electrically insulating materials, in accordance with an embodiment of the disclosure. In one embodiment, the system 200 may be a system for depositing a film 102 onto a substrate through a physical vapor deposition method (e.g., Arc-PVD or cathodic arc deposition). In such an embodiment, the system 200 may comprise a reaction chamber 206 having an interior structured to contain a substrate 201. The substrate 201 may be placed on a substrate holder 210 within the interior of the reaction chamber 206. The substrate holder 210 may comprise a heating element that may heat the substrate 201 to a desired temperature as described elsewhere herein. The interior of the reaction chamber 206 may be evacuated through output port 209 (e.g., through the use of a vacuum pump). Controlled amounts of a gas (e.g., nitrogen, argon, and/or the like) may be introduced into the reaction chamber 206 through input port 208. For instance, increasing the concentration of nitrogen may cause the resulting film 202 to have an increased electrical resistance (e.g., through nitrogen doping).

A first electrode 203 (e.g., an anode) and a second electrode 204 (e.g., a cathode target comprising the materials to be deposited onto the substrate 201) may be located within the interior of the reaction chamber 206, where the first electrode 203 and the second electrode 204 may be positioned across from one another. In some embodiments, the second electrode 204 may be a carbonaceous target cathode. The second electrode 204 may be operatively coupled to an arc source 205 which may supply a high current electrical arc that strikes the surface of the second electrode 204, thereby vaporizing a portion of the material of the second electrode 204. The vaporized material 207 may be deposited (e.g., through condensation) onto the substrate 201 as a film 202. It should be appreciated by those skilled in the art that although a single first electrode 203 (e.g., a single anode) and a single second electrode 204 (e.g., a single cathode) are depicted in FIG. 2, it is within the scope of the disclosure for the system 200 to comprise multiple first electrodes (e.g., multiple anodes) and/or multiple second electrodes (e.g., multiple cathodes). For instance, in cases in which the composition of the film requires multiple different materials, multiple different cathode targets may be used to generate vapors of the various materials needed to form the film.

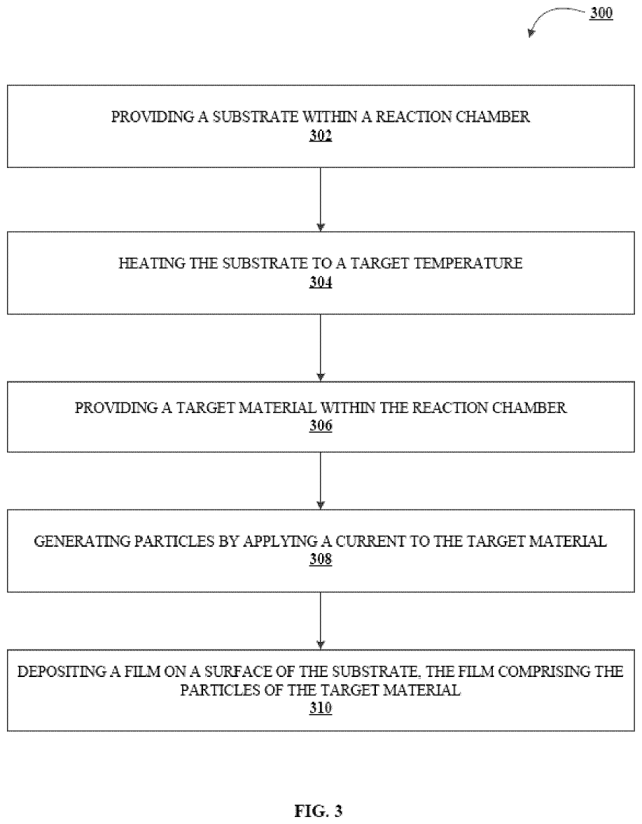

FIG. 3 illustrates a method 300 for creating thermally conductive, electrically insulating materials a film comprising thermally conductive, electrically insulating materials, in accordance with an embodiment of the disclosure. As shown in block 302, the method includes providing a substrate within a reaction chamber. The substrate may be any object that can be coated to achieve electrically insulating properties while maintaining high thermal conductivity. Accordingly, in some embodiments, the substrate may be a heat spreader, heat sink, heat exchanger, and/or the like that may be constructed from thermally and electrically conductive materials (e.g., metals such as copper, steel, aluminum, and/or the like). Reaction chamber may be a part of a system for coating the substrate (e.g., an apparatus for depositing a thin film using chemical vapor deposition and/or physical vapor deposition processes). Accordingly, the substrate may be supported by and/or reversibly attached to a substrate holder positioned within the interior of the reaction chamber.

Next, as shown in block 304, the method includes heating the substrate to a target temperature. In this regard, the substrate holder may, in some embodiments, comprise a heating element (e.g., a heating coil, ceramic heater, semiconductor, resistive heater, thick film heater, and/or the like) that, when activated (e.g., by running a current through the heating element), heats the substrate to facilitate the PVD and/or CVD process. In this regard, using PECVD and/or Arc-PVD methods may reduce the target temperatures necessary to form the film on the surface of the substrate in comparison to conventional methods. Accordingly, the target temperature may in some embodiments range from about 100 degrees Celsius to 600 degrees Celsius. In another embodiment, the target temperature may range from about 200 degrees Celsius to 400 degrees Celsius.

Next, as shown in block 306, the method includes providing a target material within the reaction chamber. The target material may comprise the materials to be deposited onto the substrate as a film. Accordingly, the target material may comprise materials such as carbon-based materials, boron-based materials, beryllium-based materials, silicon-based materials, nitride or oxide-based materials, and/or the like. In some embodiments, the method may include using a PECVD-based process to deposit the film onto the substrate. In such embodiments, the target material may be a gaseous precursor or reactant comprising one or more of the materials described herein. The gaseous precursor may be introduced into the low pressure interior of the reaction chamber such that at least a portion of the gaseous precursor diffuses into the space between the cathode and anode of the reaction chamber. In other embodiments, such as when the method includes using an Arc-PVD-based process to deposit the film onto the substrate, the target material may be a solid cathode target comprising one or more of the materials described herein. The solid cathode target may be positioned within the reaction chamber adjacent to and/or in proximity to an arc source within the reaction chamber.

Next, as shown in block 308, the method includes generating target particles by applying a current to the target material. In embodiments in which the method includes using a PECVD process, generating the target particles may comprise generating a high potential electrical field within the reaction chamber to generate a plasma of the target material. The plasma may be ignited to generate charged ions (the target particles), which may then self-assemble into a thin, layered film on the surface of the substrate.

In embodiments in which the method includes using an Arc-PVD process, generating the target particles may include striking the surface of the target material (e.g., a cathode target) with an electrical arc. The localized high temperature of the strike may vaporize at least a portion of the target material to generate a vapor (the target particles), which may then condense on the surface of the substrate. By using a PECVD and/or Arc-PVD process, the method drastically reduces deposition time, which in turn lowers production times, energy requirements, and cost for manufacturing the final product (e.g., an electrically insulated heat spreader).

Next, as shown in block 310, the method includes depositing a film on a surface of the substrate, the film comprising the target particles. The resulting film from the processes described herein may be formed from a number of different compositions. In one embodiment, the film may be a carbon-based film (e.g., a diamond-like carbon or “DLC” film) that may contain one or more allotropes of carbon, such as amorphous carbon, graphitic carbon, diamond carbon, and/or the like. In another embodiment, the film may be a boron-based film (e.g., a boron nitride film) that may contain one or more forms of boron nitride, such as amorphous boron nitride (a-BN), hexagonal boron nitride (h-BN), cubic boron nitride (c-BN), wurtzite boron nitride (w-BN), and/or the like. In yet other embodiments, the film may be a beryllium-based film (e.g., a beryllium oxide film). In yet other embodiments, the film may be a silicon-based film (e.g., a silicon carbonitride film).

A table showing the material properties of the various forms of carbon and boron nitride is provided below.

TABLE 1
Material Properties of Boron Nitride and Carbon

| | Boron Nitride | | | | | |
|---|---|---|---|---|---|---|
| | Hexagonal | Cubic | | Carbon | | |
| Material Property | BN | BN | Amorphous | Graphite | Diamond | Amorphous |
| Thermal conductivity | 30-600 ∥, | 740 | 3 | 200-2000 ∥, | 600- | 1-10 |
| (W/(m · K)) | 30 ⊥ | | | 2-800 ├ | 2000 | |
| Electrical Resistivity | 10⁸-10¹³ | 10¹⁰ | 80 | 10⁻⁵ | 10¹¹- | 1 × 10⁶ |
| (Ω · m) | | | | | 10¹⁸ | |
| Dielectric Breakdown | 10-12∥, | 10 | 10 | N/A | 10 | 2 |
| Strength (MV/cm) | 2-6⊥ | | | | | |

The parameters of the deposition method and the film itself may be modified to account for the material properties of the films described herein. For instance, the thickness of the film may be modified appropriately for the material used such that the film is thick enough to sufficient electrical resistance while maintaining sufficient thermal conductivity for the application. Furthermore, it should be understood that the resulting film may comprise different ratios of the various forms of the material. For instance, for carbon-based coatings, the ratios between graphitic and diamond forms of amorphous carbon may be modified to increase the thermal conductivity of the film (e.g., by increasing the diamond to graphitic forms).

As will be appreciated by one of ordinary skill in the art, the present disclosure may be embodied as an apparatus (including, for example, a system, a machine, a device, a computer program product, and/or the like), as a method (including, for example, a business process, a computer-implemented process, and/or the like), as a computer program product (including firmware, resident software, micro-code, and the like), or as any combination of the foregoing. Many modifications and other embodiments of the present disclosure set forth herein will come to mind to one skilled in the art to which these embodiments pertain having the benefit of the teachings presented in the foregoing descriptions and the associated drawings. Although the figures only show certain components of the methods and systems described herein, it is understood that various other components may also be part of the disclosures herein. In addition, the method described above may include fewer steps in some cases, while in other cases may include additional steps. Modifications to the steps of the method described above, in some cases, may be performed in any order and in any combination.

Therefore, it is to be understood that the present disclosure is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A method for creating thermally conductive, electrically insulating materials, the method comprising:
providing a substrate within a reaction chamber;
includes heating the substrate to a target temperature;
providing a target material within the reaction chamber;
generating target particles by applying a current to the target material; and
depositing a film on a surface of the substrate, the film comprising the target particles.

2. The method of claim 1, wherein the target material is a gaseous precursor of the film, wherein the target particles comprise charged ions of the gaseous precursor, wherein generating the target particles further comprises:
introducing the gaseous precursor into the reaction chamber such that at least a portion of the gaseous precursor is positioned between a first electrode and a second electrode within the reaction chamber;
generating an electrical field within the reaction chamber to generate a plasma of the gaseous precursor; and
igniting the plasma to generate the charged ions.

3. The method of claim 1, wherein the target material is a cathode target, wherein the target particles comprise a vapor of the target material, wherein generating the target particles further comprises:
activating an arc source located proximate to the cathode target within the reaction chamber; and
generating an electrical arc that impacts a surface of the cathode target, wherein the electrical arc causes at least a portion of the cathode target to vaporize.

4. The method of claim 1, wherein the method further comprises evacuating an interior of the reaction chamber to a target interior pressure.

5. The method of claim 4, wherein the target interior pressure ranges from about 1 torr to 2 torr.

6. The method of claim 1, wherein the target temperature ranges from about 200 degrees Celsius to 400 degrees Celsius.

7. The method of claim 1, wherein a thickness of the film ranges from about 5 microns to 20 microns.

8. The method of claim 1, wherein the film is a carbon-based film comprising at least one of amorphous carbon, graphitic carbon, or diamond carbon.

9. The method of claim 1, wherein the film is a boron nitride-based film comprising at least one of amorphous boron nitride, hexagonal boron nitride, or cubic boron nitride.

10. The method of claim 1, wherein the film is a beryllium oxide-based film.

11. The method of claim 1, wherein the film is a silicon carbonitride-based film.

12. The method of claim 1, wherein the substrate is at least one of a heat spreader, heat sink, or heat exchanger.

13. The method of claim 12, wherein the substrate is constructed from copper or aluminum.

14. A system for creating thermally conductive, electrically insulating materials, the system comprising:
a reaction chamber comprising an interior;
an output port operatively coupled to the interior of the reaction chamber, the output port comprising a vacuum pump; and
an input port operatively coupled to the interior of the reaction chamber, wherein the interior of the reaction chamber comprises:
one or more electrodes operatively coupled to a power source;
a substrate positioned adjacent to or reversibly attached to a substrate holder, wherein the substrate holder comprises a heating element; and
a mass of target particles, wherein the target particles form a film on a surface of the substrate.

15. The system of claim 14, wherein target particles comprise charged ions formed from a plasma formed from a gaseous precursor of the film, wherein the power source is a radio-frequency (“RF”) power source that generates an electrical field within the reaction chamber that creates the plasma from the gaseous precursor.

16. The system of claim 14, wherein the one or more electrodes comprises a cathode target, wherein the target particles comprise a vapor formed from the cathode target, wherein the reaction chamber further comprises an arc source positioned proximate to the cathode target, wherein the arc source, when activated, causes at least a portion of the cathode target to vaporize.

17. The system of claim 14, wherein a thickness of the film ranges from about 5 microns to 20 microns.

18. The system of claim 14, wherein the film is a carbon-based film comprising at least one of amorphous carbon, graphitic carbon, or diamond carbon.

19. The system of claim 14, wherein the film is a boron nitride-based film comprising at least one of amorphous boron nitride, hexagonal boron nitride, or cubic boron nitride.

20. The system of claim 14, wherein the substrate is at least one of a heat spreader, heat sink, or heat exchanger.

21. A product, comprising:
a substrate having a surface, wherein the substrate has a high thermal conductivity; and
a film applied to the surface of the substrate, wherein the film is a vapor deposited film having a high thermal conductivity and a high electrical resistivity.

22. The product of claim 21, wherein the thermal conductivity of the substrate is at least 100 W/m·k.

23. The product of claim 21, wherein the thermal conductivity of the substrate ranges from about 150 W/m·k to about 400 W/m·k.

24. The product of claim 21, wherein the thermal conductivity of the substrate is greater than 400 W/m·k.

25. The product of claim 21, wherein the thermal conductivity of the film is at least 1 W/m·k.

26. The product of claim 21, wherein the thermal conductivity of the film ranges from about 2 W/m·k to about 5 W/m·k.

27. The product of claim 21, wherein the thermal conductivity of the film is greater than 100 W/m·k.

28. The product of claim 21, wherein the electrical resistivity of the film is at least 1 MΩ/m.

29. The product of claim 21, wherein a thermal resistivity of the film is less than 1 m·K/W.

30. The product of claim 21, wherein a dielectric strength of the film is at least 500 V/μm.
